(19) United States
(12) Patent Application Publication
(10) Pub. No.: US 2016/0049496 A1
(43) Pub. Date: Feb. 18, 2016

(54) MOS TRANSISTOR AND SEMICONDUCTOR PROCESS FOR FORMING EPITAXIAL STRUCTURE

(71) Applicant: UNITED MICROELECTRONICS CORP., Hsin-Chu City (TW)

(72) Inventors: Man-Ling Lu, Taoyuan County (TW); Yu-Hsiang Hung, Tainan City (TW); Chung-Fu Chang, Tainan City (TW); Yen-Liang Wu, Taipei City (TW); Wen-Jiun Shen, Yunlin County (TW); Chia-Jong Liu, Ping-Tung County (TW); Ssu-I Fu, Kaohsiung City (TW); Yi-Wei Chen, Taichung City (TW)

(21) Appl. No.: 14/495,907

(22) Filed: Sep. 25, 2014

(30) Foreign Application Priority Data
Aug. 12, 2014 (CN) 201410393840.9

(51) Int. Cl. H01L 29/66; H01L 29/06; H01L 21/02; H01L 29/78

(52) U.S. Cl. CPC H01L 29/66553; H01L 29/78; H01L 29/0649; H01L 21/0206

(57) ABSTRACT

A MOS transistor including a gate structure, an epitaxial spacer and an epitaxial structure is provided. The gate structure is disposed on a substrate. The epitaxial spacer is disposed on the substrate besides the gate structure, wherein the epitaxial spacer includes silicon and nitrogen, and the ratio of nitrogen to silicon is larger than 1.3. The epitaxial structure is disposed in the substrate besides the epitaxial spacer. A semiconductor process includes the following steps for forming an epitaxial structure. A gate structure is formed on a substrate. An epitaxial spacer is formed on the substrate besides the gate structure for defining the position of an epitaxial structure, wherein the epitaxial spacer includes silicon and nitrogen, and the ratio of nitrogen to silicon is larger than 1.3. The epitaxial structure is formed in the substrate besides the epitaxial spacer.

### BACKGROUND OF THE INVENTION

1. Field of the Invention

The present invention relates generally to a MOS transistor and a semiconductor process for forming an epitaxial structure, and more specifically to a MOS transistor including an epitaxial spacer having a ratio of nitrogen to silicon larger than 1.3, and a semiconductor process for forming an epitaxial structure.

2. Description of the Prior Art

For decades, chip manufacturers have made metal-oxide-semiconductor (MOS) transistors faster by making them smaller. As semiconductor processes advance to the very deep sub-micron era such as 65-nm node or beyond, how to increase the driving current for MOS transistors has become a critical issue. Crystal strain technology has been developed as one means to improve device performance. Putting a strain on a semiconductor crystal alters the speed at which charges move through that crystal. Strain makes MOS transistors work better by enabling electrical charges, such as electrons, to pass more easily through the silicon lattice of the gate channel.

Attempts have been made to use a strained silicon layer grown epitaxially on a silicon substrate with a silicon germanium (SiGe) layer or a silicon carbide (SiC) layer disposed in between. In this type of MOS transistor, a biaxial tensile strain occurs in the epitaxy silicon layer due to the presence of silicon germanium or silicon carbide which has a different lattice constant than silicon. As a result, the band structure alters and the carrier mobility increases, which enhances the speed performance of the MOS transistors.

Strained silicon processes have to coordinate with other semiconductor processes, so that other parts of a formed MOS transistor will not be degraded while the speed of the MOS transistor is enhanced due to the strained silicon technology.

### SUMMARY OF THE INVENTION

The present invention provides a MOS transistor and a semiconductor process for forming an epitaxial structure, by forming a silicon and nitrogen containing epitaxial spacer having a ratio of nitrogen to silicon larger than 1.3. This prevents an epitaxial structure from being formed on the epitaxial spacer while the epitaxial structure is formed on a substrate.

The present invention provides a MOS transistor including a gate structure, an epitaxial spacer and an epitaxial structure. The gate structure is disposed on a substrate. The epitaxial spacer is disposed on the substrate besides the gate structure, wherein the epitaxial spacer includes silicon and nitrogen, and the ratio of nitrogen to silicon is larger than 1.3. The epitaxial structure is disposed in the substrate besides the epitaxial spacer.

The present invention provides a semiconductor process including the following steps for forming an epitaxial structure. A gate structure is formed on a substrate. An epitaxial spacer is formed on the substrate besides the gate structure for defining a location of an epitaxial structure, wherein the epitaxial spacer includes silicon and nitrogen, and the ratio of nitrogen to silicon is larger than 1.3. The epitaxial structure is formed in the substrate besides the epitaxial spacer.

The present invention provides the MOS transistor and the semiconductor process for forming an epitaxial structure, which forms a silicon and nitrogen containing epitaxial spacer having a ratio of nitrogen to silicon larger than 1.3. In this way, the low silicon content of the epitaxial spacer can be ensured, so that an epitaxial structure attaching on the epitaxial spacer can be prevented while the epitaxial structure is formed on a substrate besides the epitaxial spacer. Problems such as the pollution of other parts of the MOS transistor and short circuits leading to a reduction in yield can thereby be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 schematically depict a cross-sectional view of a semiconductor process for forming an epitaxial structure according to an embodiment of the present invention.

### DETAILED DESCRIPTION

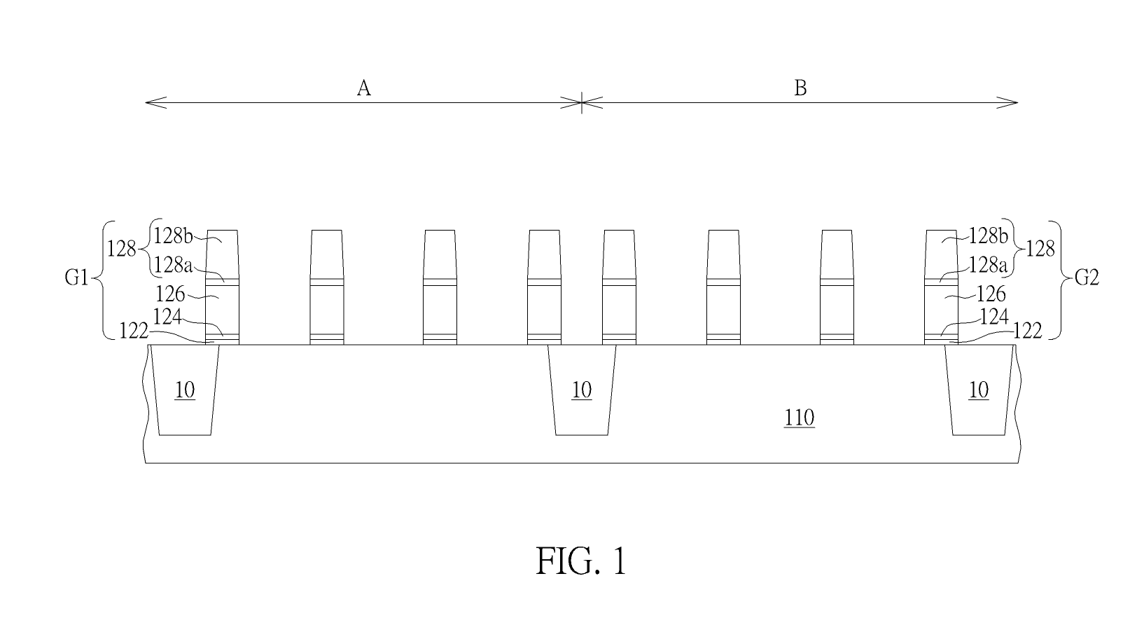

As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. An isolation structure 10 may be formed between each transistor to isolate these transistors. In this embodiment, the substrate 110 is divided into a first area A and a second area B by the isolation structure 10, wherein the first area A is a PMOS transistor area while the second area B is an NMOS transistor area, but is not limited thereto. The isolation structure 10 may be a shallow trench isolation (STI) structure, which may be formed by a shallow trench isolation (STI) process, but is not limited thereto.

A plurality of gate structures G1 are formed on the substrate 110 of the first area A while a plurality of gate structures G2 are formed on the substrate 110 of the second area B. Each of the gate structures G1 and G2 is a stacked structure, which may include a buffer layer 122, a dielectric layer 124, a gate layer 126 and a cap layer 128 stacked from bottom to top. More precisely, the method of forming the gate structures G1 and G2 may include the following steps. A buffer layer (not shown), a dielectric layer (not shown), a gate layer (not shown) and a cap layer (not shown) sequentially cover the substrate 110, and these layers are then patterned to form the buffer layer 122, the dielectric layer 124, the gate layer 126 and the cap layer 128. The cap layer 128 may be a single layer or a multilayer. In this embodiment, the cap layer 128 is a dual layer including a bottom cap layer 128a and a top cap layer 128b from bottom to top, so that the bottom cap layer 128a and the top cap layer 128b can serve as etching stop layers or polishing stop layers in later etching processes or polishing processes, respectively, due to the etching selectivity or polishing selectivity of the bottom cap layer 128a and the top cap layer 128b. Moreover, there are four gate structures G1 on the substrate 110 of the first area A and four gate structures G2 on the substrate 110 of the second area B depicted in the figures, but the number of the gate structures G1 and G2 are not restricted thereto.

The buffer layer 122 may include an oxide layer; the gate dielectric layer 124 may be a dielectric layer having a high dielectric constant, such as the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST); the gate layer 126 may be a polysilicon layer or a sacrificial layer replaced with a metal gate in later processes; the bottom cap layer 128a may be a nitride layer, and the top cap layer 128b may be an oxide layer.

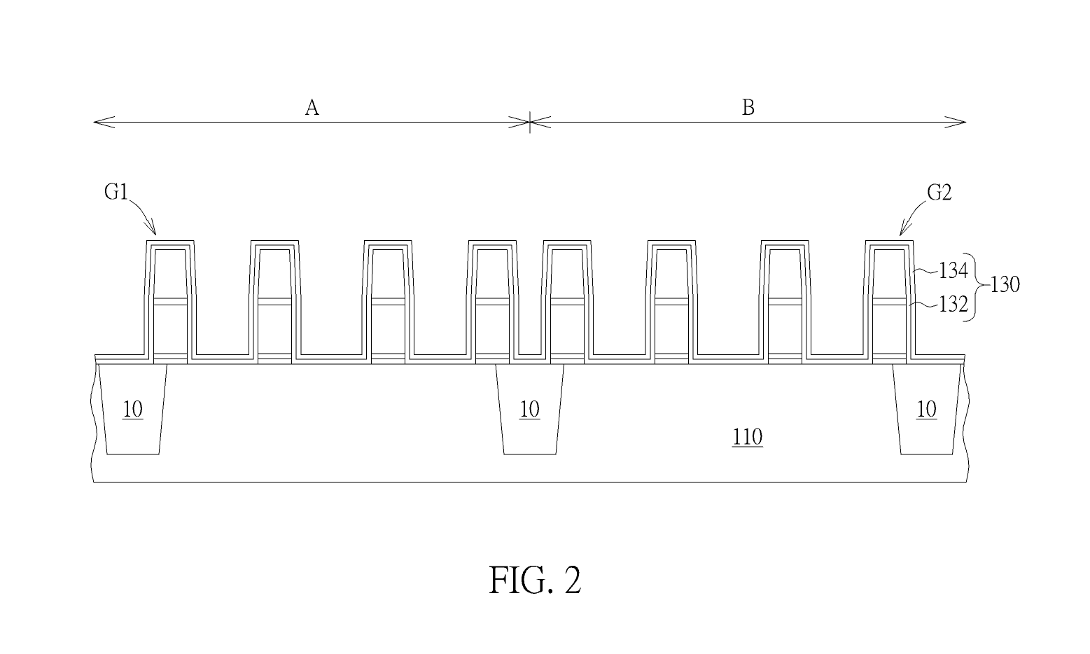

As shown in FIG. 2, a spacer material 130 conformally covers the substrate 110 and the gate structures G1 and G2 in the first area A and the second area B. In this embodiment, the spacer material 130 is a dual layer, which may include an inner spacer material 132 and an outer spacer material 134. In another embodiment, the spacer material 130 may be a single layer, depending upon a desired formed MOS transistor. It is emphasized that, as the spacer material 130 is a dual spacer, the outer spacer material 134 of the present invention contains silicon and nitrogen, and the ratio of nitrogen to silicon is larger than 1.3. As the spacer material 130 is a single layer, the spacer material 130 contains silicon and nitrogen, and the ratio of nitrogen to silicon is larger than 1.3. Since the outer spacer material 134 or the spacer material 130 has a ratio of nitrogen to silicon larger than 1.3, elements of a later formed epitaxial structure for a PMOS transistor such as germanium can be included to prevent the epitaxial structure from forming or attaching to the outer spacer material 134 or the spacer material 130. More precisely, the ratio of nitrogen to silicon of the outer spacer material 134 or the spacer material 130 is obtained by surface analysis of X-ray photoelectron spectroscopy (XPS) technology, which can be applied to measure the percentage of every element included in an outer atomic layer of a solid structure.

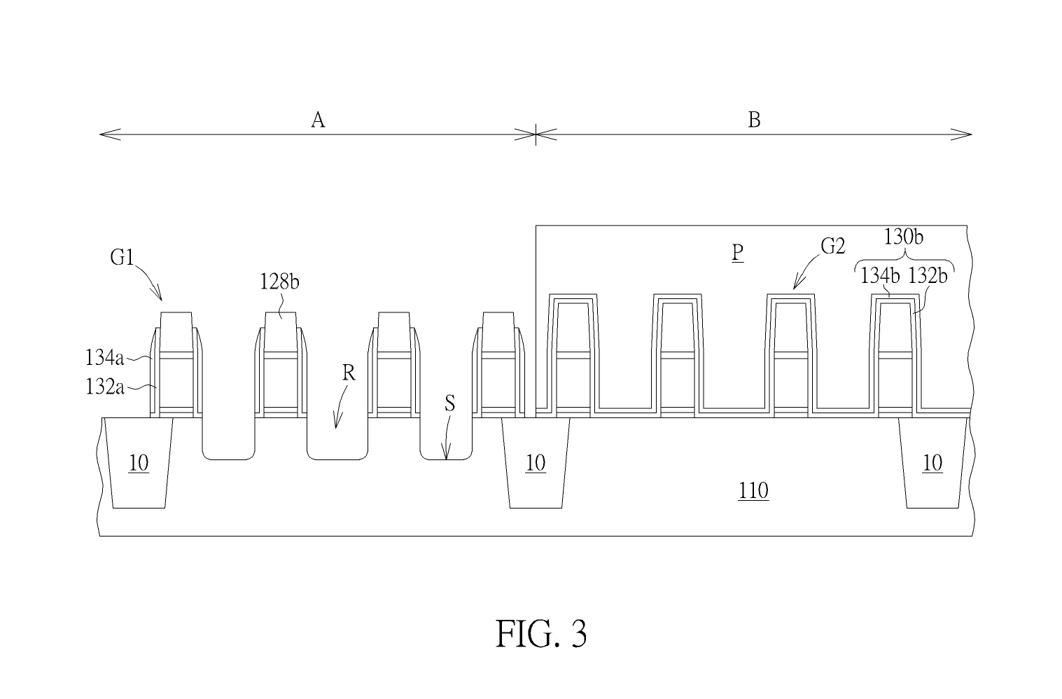

As shown in FIG. 3, a photoresist (not shown) may be formed in a blanket shape and patterned to form a patterned photoresist P, wherein the patterned photoresist P only covers the second area B without covering the first area A. Then, processes such as an etching process may be performed to etch the exposed spacer material 130 of the first area A, so that spacers 132a and epitaxial spacers 134a are formed on the substrate 110 besides the gate structures G1 while a spacer material 130b of the second area B reserved. The spacer material 130b includes an inner spacer material 132b and an outer spacer material 134b. In detail, the outer spacer material 134 of the first area A is etched to form epitaxial spacers 134a on the substrate 110 besides the gate structures G1, while the inner spacer material 132 of the first area A is etched to form the spacers 132a located on the substrate 110 and between the gate structures G1 and the epitaxial spacers 134a. In this embodiment, the spacers 132a and the epitaxial spacers 134a are formed by sequentially depositing the inner spacer material 132 and the outer spacer material 134 and then etching, epitaxial spacers 134a to have boat-shaped cross-sectional profiles and the spacers 132a to have L-shaped cross-sectional profiles. In another embodiment, the inner spacer material 132 and the outer spacer material 134 of the first area A may be deposited and etched respectively, so that the spacers 132a and the epitaxial spacers 134a can both have boat-shaped cross-sectional profiles, which depends upon requirements. Furthermore, the top cap layers 128b in this embodiment serve as etching stop layers and are exposed while the epitaxial spacer material 130 of the first area A is etched to form the spacers 132a and the epitaxial spacers 134a. In another embodiment, the bottom cap layers 128a may additionally serve as etch stop layers while the spacers 132a and the epitaxial spacers 134a are formed, so that the top cap layers 128b will be removed and the bottom cap layers 128a will be exposed. A part of the top cap layers 128b or the bottom cap layers 128a may be etched through adjusting the etching selectivity of the top cap layers 128b and the bottom cap layers 128a, so that heights of the gate structures G1 can be adjusted.

It is noted that, since the outer spacer material 134 of the present invention includes silicon and nitrogen, and the ratio of nitrogen to silicon is larger than 1.3, the epitaxial spacers 134a formed by the outer spacer material 134 also contain silicon and nitrogen, and the ratio of nitrogen to silicon is also larger than 1.3. A later formed epitaxial structure can therefore prevented from attaching to the epitaxial spacers 134a as the epitaxial structure is formed on the substrate 110. In a preferred embodiment, the epitaxial spacers 134a have a ratio of nitrogen to silicon larger than or equal to 1.37, so that the later formed epitaxial structure can be completely prevented from attaching to the epitaxial spacers 134a due to the low silicon content. More precisely, the epitaxial spacers 134a may be silicon nitride spacers, and the silicon content of the silicon nitride spacers is lower than 43%, wherein the percentage is obtained by the ratio of nitrogen to silicon larger than 1.3, but is not limited thereto.

In one case, the silicon content of the inner spacer material 132 is higher than 43%, therefore the silicon content of the spacers 132a formed by the inner spacer material 132 is also higher than 43%. The silicon content of the spacers 132a and the epitaxial spacers 134a may therefore be different; or the silicon content of the epitaxial spacers 134a may be lower than the silicon content of the spacers 132a. Hence, the inner spacers 132a can have the advantages of hardness and flexible material to achieve processing requirements while the outer epitaxial spacers 134a can prevent a later formed epitaxial structure from attaching to surfaces of the epitaxial spacers 134a. The spacers 132a may be silicon oxide spacers, silicon oxynitride spacers or carbon-containing silicon nitride spacers, but are not limited thereto. As the spacers 132a are carbon-containing silicon nitride spacers, their ratio of nitrogen to silicon may be 1.15. Compared to the spacers 132a having a 1.15 ratio of nitrogen to silicon, epitaxial structures are harder to attach to silicon nitride spacers having the ratio of nitrogen to silicon which is larger than or equal to 1.37. Thus, the epitaxial structures can be prevented from growing on the spacers as the silicon nitride spacers having a ratio of nitrogen to silicon larger than or equal to 1.37 cover the carbon-containing silicon nitride spacers having a 1.15 ratio of nitrogen to silicon.

The spacers 132a and the epitaxial spacers 134a of this embodiment are applied to define positions of epitaxial structures in order for them to be formed. In other embodiments, the spacers 132a and the epitaxial spacers 134a may be formed separately, and the spacers 132a can be formed for defining and forming lightly doped source/drains or source/drains before the epitaxial spacers 134a are formed, in order to define and form the epitaxial structures.

In this embodiment, the substrate 110 besides the epitaxial spacers 134a is etched to form recesses R in the substrate 110 for forming epitaxial structures therein. In a preferred embodiment, one single etching process is performed to uninterruptedly and continuously etch the outer spacer material 134 to form the epitaxial spacers 134a and etch the substrate 110 to form the recesses R. This simplifies the processing steps, reducing processing costs and saving processing time. After the recesses R are formed, the patterned photoresist P may be removed immediately.

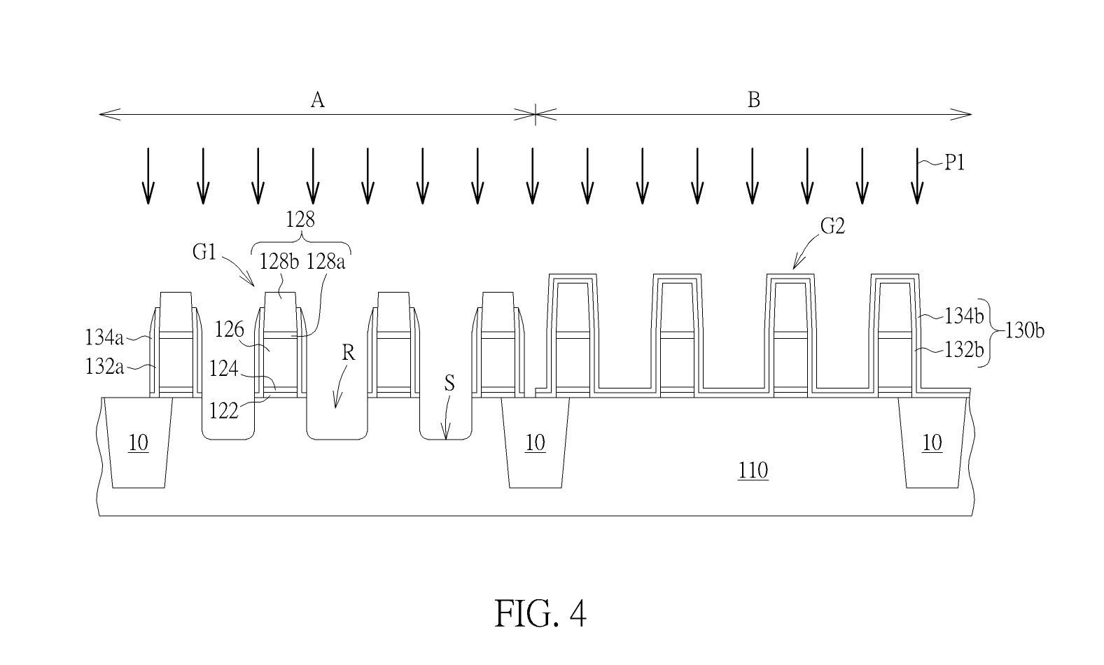

As shown in FIG. 4, after the recesses R are formed and before epitaxial structures are formed, a clean and modifying process P1 may be performed to clean surfaces S of the recesses R for improving the qualities of the epitaxial structures. In one case, a hydrofluoric acid (HF) process, a room temperature hydrogen peroxide and sulfuric acid process and a standard clean 1 process may be performed sequentially to clean the surfaces S of the recesses R.

In a preferred case, a high temperature hydrogen peroxide and sulfuric acid containing process and a standard clean 1 process are performed instead to clean the surfaces S of the recesses R, so that macromolecular residues left after previously performed etching processes can be removed and the surfaces S of the recesses R can contain sufficient oxygen. Still preferably, the processing temperature of the high temperature hydrogen peroxide and sulfuric acid containing process is about 150° C.˜170° C., so that the high temperature can efficiently remove macromolecular residues and native oxides, making epitaxial structures easier to grow on the surfaces S of the recesses R. It is noted that a diluted hydrofluoric acid (DHF) containing process is not applied in this embodiment, thereby native oxides on surfaces of the epitaxial spacers 134a and the outer spacer material 134b can be reserved to reduce the possibility of the epitaxial structures from attaching to the epitaxial spacers 134a and the outer spacer material 134b.

Furthermore, an oxygen stripping (O₂ stripping) process may be performed before the high temperature hydrogen peroxide and sulfuric acid containing process and the standard clean 1 process are performed, to clean the surfaces S of the recesses R as well as remove the patterned photoresist P. It is noted that the surfaces of the epitaxial spacers 134a and the outer spacer material 134b can contain sufficient oxygen through performing the oxygen stripping process, thus reducing the possibility of the epitaxial structures attaching to the epitaxial spacers 134a and the outer spacer material 134b.

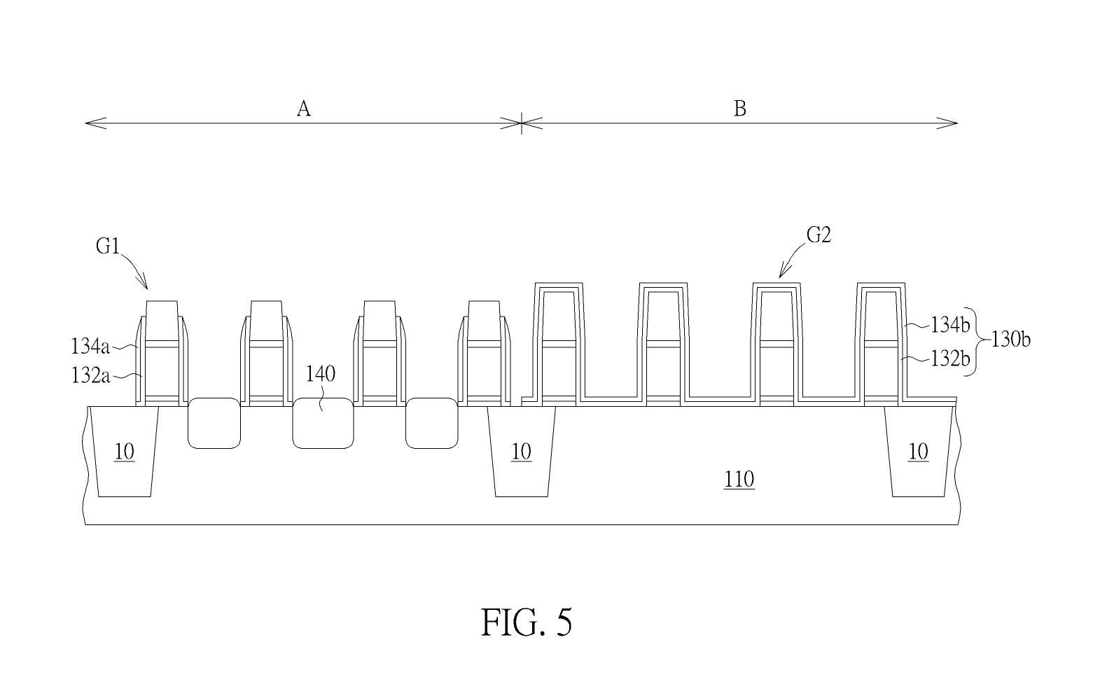

As shown in FIG. 5, epitaxial structures 140 are formed in the recesses R besides the epitaxial spacers 134a. In this embodiment, as the first area A is a PMOS transistor area, the epitaxial structures 140 may be silicon germanium epitaxial structures suitable for PMOS transistors. In this embodiment, the recesses R are formed first and the epitaxial structures 140 are formed in the recesses R, but the epitaxial structures 140 may be directly formed in the substrate 110 besides the epitaxial spacers 134a without forming the recesses R.

Thereafter, processes of the present invention similar to the aforesaid processes can be applied in the second area B to prevent the epitaxial structures 140 formed in the second area B from growing on the epitaxial spacers 134a in the second area B. Moreover, a CMOS transistor having a PMOS transistor and an NMOS transistor is applied in this embodiment, but the present invention can also be applied to a single transistor such as a NMOS transistor or a PMOS transistor. Processes forming epitaxial structures using epitaxial spacers or masks similar to the epitaxial spacers can also be applied to the present invention.

The embodiment shown in FIGS. 1-5 is an example of a planar transistor, but the present invention can also be applied to a multi-gate MOSFET, which has a cross-sectional profile similar to the structure of FIGS. 1-5.

To summarize, the present invention provides a MOS transistor and semiconductor process for forming an epitaxial structure, which forms a silicon and nitrogen containing an epitaxial spacer having a ratio of nitrogen to silicon larger than 1.3. In this way, the low silicon content of the epitaxial spacer can be ensured to prevent the epitaxial structure from attaching to the epitaxial spacer when the epitaxial structure is formed on a substrate besides the epitaxial spacer. Problems such as the pollution of other parts of the MOS transistor and short circuits leading to poor yields can be avoided.

Preferably, the epitaxial spacer has a ratio of nitrogen to silicon larger than or equal to 1.37, for ensuring the low silicon content of the epitaxial spacer and preventing the epitaxial structure from growing on the epitaxial spacer. In one case, the epitaxial spacer may be a silicon nitride spacer, and the silicon content of the epitaxial spacer is less than 43%.

A high temperature hydrogen peroxide and sulfuric acid containing process and a standard clean 1 process may be performed on surfaces of the substrate or a recess before the epitaxial structure is formed, to clean and modify the surface of the substrate or the recess. Epitaxial structure having good qualities can thereby be formed. The processing temperature of the high temperature hydrogen peroxide and sulfuric acid containing process is preferably about 150° C.˜170° C. Only the high temperature hydrogen peroxide and sulfuric acid containing process and the standard clean 1 process are performed without performing a diluted hydrofluoric acid (DHF) containing process, thereby native oxides on a surface of the epitaxial spacers can be reserved, which reduces the possibility of the epitaxial structure attaching to the surface of the epitaxial spacer.

Still preferably, an oxygen stripping process may be performed before the high temperature hydrogen peroxide and sulfuric acid containing process and the standard clean 1 process are performed, to further clean the surface of the substrate or the recess and remove a patterned photoresist formed for etching the epitaxial spacer and the recess. The surface of the epitaxial spacer can contain sufficient oxygen through performing the oxygen stripping process, thus reducing the possibility of the epitaxial structure attaching to the epitaxial spacer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A MOS transistor, comprising:
a gate structure disposed on a substrate;
an epitaxial spacer disposed on the substrate besides the gate structure, wherein the epitaxial spacer comprises silicon and nitrogen, and the ratio of nitrogen to silicon is larger than 1.3; and
an epitaxial structure disposed in the substrate besides the epitaxial spacer.

2. The MOS transistor according to claim 1, wherein the ratio of nitrogen to silicon of the epitaxial spacer is larger than or equal to 1.37.

3. The MOS transistor according to claim 1, wherein the epitaxial spacer comprises a silicon nitride spacer, and the silicon content of the silicon nitride spacer is lower than 43%.

4. The MOS transistor according to claim 1, further comprising: a spacer disposed between the gate structure and the epitaxial spacer, wherein the silicon content of the spacer is larger than 43%.

5. The MOS transistor according to claim 4, wherein the spacer comprises a silicon oxide spacer, a silicon oxynitride spacer or a carbon-containing silicon nitride spacer.

6. The MOS transistor according to claim 5, wherein the ratio of nitrogen to silicon of the carbon-containing silicon nitride spacer is 1.15.

7. A semiconductor process for forming an epitaxial structure, comprising:
forming a gate structure on a substrate;
forming an epitaxial spacer on the substrate besides the gate structure for defining a location of an epitaxial structure, wherein the epitaxial spacer comprises silicon and nitrogen, and the ratio of nitrogen to silicon is larger than 1.3; and
forming the epitaxial structure in the substrate beside the epitaxial spacer.

8. The semiconductor process according to claim 7, wherein the ratio of nitrogen to silicon of the epitaxial spacer is larger than or equal to 1.37.

9. The semiconductor process according to claim 7, wherein the epitaxial spacer comprises a silicon nitride spacer, and the silicon content of the silicon nitride spacer is lower than 43%.

10. The semiconductor process according to claim 7, wherein the epitaxial structure comprises a silicon germanium epitaxial structure.

11. The semiconductor process according to claim 7, further comprising:
forming a spacer on the substrate besides the gate structure before the epitaxial spacer is formed, and the silicon content of the spacer is larger than 43%.

12. The semiconductor process according to claim 11, wherein the spacer comprises a silicon oxide spacer, a silicon oxynitride spacer or a carbon-containing silicon nitride spacer.

13. The semiconductor process according to claim 12, wherein the ratio of nitrogen to silicon of the carbon-containing silicon nitride spacer is 1.15.

14. The semiconductor process according to claim 7, further comprising:
etching the substrate besides the epitaxial spacer to form a recess in the substrate before the epitaxial structure is formed, so that the epitaxial structure is formed in the recess.

15. The semiconductor process according to claim 14, further comprising:
sequentially performing a high temperature hydrogen peroxide and sulfuric acid containing process and a standard clean 1 process to clean a surface of the recess before the epitaxial structure is formed.

16. The semiconductor process according to claim 15, wherein the processing temperature of the high temperature hydrogen peroxide and sulfuric acid containing process is in a range of 150° C.˜170° C.

17. The semiconductor process according to claim 15, further comprising:
performing an oxygen stripping process to clean the surface of the recess before the high temperature hydrogen peroxide and sulfuric acid containing process and the standard clean 1 process are performed.

18. The semiconductor process according to claim 14, wherein the epitaxial spacer and the recess are formed continuously and uninterruptedly.

19. The semiconductor process according to claim 7, wherein the step of forming the epitaxial spacer comprises:
blanketly covering an epitaxial spacer material on the gate structure and the substrate; and
etching the epitaxial spacer material to form the epitaxial spacer.
